(19) United States
(12) Patent Application Publication
(10) Pub. No.: US 2022/0238596 A1
(43) Pub. Date: Jul. 28, 2022

(54) MICRO LIGHT EMITTING DIODE DISPLAY DEVICE

(71) Applicant: MACROBLOCK, INC., Hsinchu (TW)

(72) Inventors: Chen-Yuan Kuo, Hsinchu (TW); Chen-Chi Yang, Hsinchu (TW); Mei-Tan Wang, Hsinchu (TW); Che-Wei Chang, Hsinchu (TW)

(73) Assignee: MACROBLOCK, INC., Hsinchu (TW)

(21) Appl. No.: 17/647,182

(22) Filed: Jan. 6, 2022

(30) Foreign Application Priority Data
Jan. 27, 2021 (TW) 110103079

(51) Int. Cl. H01L 27/15; H01L 33/50; H01L 33/10; H01L 33/38; H01L 33/62; H01L 33/48

(52) U.S. Cl. CPC H01L 27/156; H01L 33/502; H01L 33/486; H01L 33/382; H01L 33/62; H01L 33/10

(57) ABSTRACT

A micro light emitting diode display device includes a light-transmissive unit, a plurality of light emitting units and a plurality of converting units. The light-transmissive unit includes a protective layer which has opposite first and second surfaces. The light emitting units are arranged in an array on the second surface of the protective layer and each of the light emitting units includes first, second and third light emitting portions. The converting units are disposed on the first surface of the protective layer in positions corresponding to the light emitting units, respectively, and each of the converting units includes a reflecting feature, and first and second wavelength converting elements.

### CROSS-REFERENCE TO RELATED APPLICATION

This application claims priority of Taiwanese Invention Patent Application No. 110103079, filed on Jan. 27, 2021.

### FIELD

The disclosure relates to a micro light emitting diode (micro-LED) display device, and more particularly to a common-cathode micro-LED display device.

### BACKGROUND

Light emitting diodes (LEDs) have become the mainstream of illumination and light source for displays due to various advantages such as small volume, high brightness, long lifetime, low heat emission, improved energy efficiency, etc. Micro-LEDs, which shares advantages similar to those of traditional LEDs, such as high brightness, high efficiency and high reliability, include dies having dimensions which are shrank to be less than one-tenth the size of a conventional LED die, such that the micro-LEDs might have more extracted lights and an increased number of dies per unit area compared with those of traditional LEDs. Therefore, the micro-LEDs could be applied to thin, highly efficient and flexible displays, and are considered to be the next-generation display technology.

Although the micro-LEDs have superior properties due to their reduced dimensions, mass transfer of the micro-LEDs in commercialization thereof still faces problems. Further, the micro-LEDs applied to the displays might have a wide-angle light distribution which might result in light loss.

### SUMMARY

Therefore, an object of the disclosure is to provide a micro light emitting diode (micro-LED) display device that can alleviate at least one of the drawbacks of the prior art.

According to the disclosure, the micro-LED display device includes a light-transmissive unit, a plurality of light emitting units and a plurality of converting units. The light-transmissive unit includes a protective layer which has a first surface and a second surface opposite to the first surface. The light emitting units are arranged in an array on the second surface of the protective layer, and each of the light emitting units includes a first light emitting portion, a second light emitting portion, and a third light emitting portion which emit lights with the same original wavelength.

Each of the first, second and third light emitting portions includes a first type semiconductor layer, a light emitting layer and a second type semiconductor layer which are sequentially stacked on the second surface of the protective layer such that the lights respectively from the first, second and third light emitting portions are permitted to pass through the light-transmissive unit to emit outward from the first surface of the protective layer, and such that the first type semiconductor layers of the first, second and third light emitting portions are integrally formed while the light emitting layers of the first, second and third light emitting portions are spaced apart from one another.

The converting units are disposed on the first surface of the protective layer in positions corresponding to the light emitting units, respectively. Each of the converting units includes a reflecting feature, a first wavelength converting element and a second wavelength converting element. The reflecting feature is formed on the first surface of the protective layer, and includes three inner peripheral surfaces which respectively define three through holes in positions corresponding to the first, second and third light emitting portions of the respective light emitting unit, respectively. An included angle between the first surface of the protective layer and each of the inner peripheral surfaces is greater than 90 degrees.

The first and second wavelength converting elements are respectively formed in two of the through holes in positions corresponding to the first and second light emitting portions of the respective light emitting unit such that when the lights from the first and second light emitting portions respectively pass through the first and second wavelength converting elements, the lights from the first and second light emitting portions are respectively converted to have a first predetermined wavelength and a second predetermined wavelength which are different from the original wavelength.

### BRIEF DESCRIPTION OF THE DRAWINGS

Other features and advantages of the disclosure will become apparent in the following detailed description of the embodiments with reference to the accompanying drawings, of which:

FIG. 1 is a schematic bottom view showing a first embodiment of a micro-LED display device according to the disclosure, except that a reflecting layer and a circuit board are omitted therefrom;

FIG. 2 is a schematic cross-sectional view taken along line II-II of FIG. 1, but includes the reflective layer and the circuit board;

FIGS. 3 and 4 are similar to FIG. 2, and illustrate consecutive steps for making the micro-LED display device shown in FIG. 2;

FIG. 5 is a schematic cross-sectional view of the first embodiment taken along line V-V of FIG. 1, but includes the reflective layer and the circuit board;

FIG. 6 is a schematic cross-sectional view of the first embodiment taken along line VI-VI of FIG. 1, but includes the reflective layer and the circuit board;

FIG. 7 is a schematic cross-sectional view illustrating a variation of the first embodiment shown in FIG. 2;

FIG. 8 is a circuit diagram illustrating an operation of the first embodiment shown in FIG. 1; and

FIG. 9 is a partial bottom view showing a second embodiment of a micro-LED display device according to the disclosure, except that a reflecting layer and a circuit board are omitted therefrom.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics. It should be noted that the drawings, which are for illustrative purposes only, are not drawn to scale, and are not intended to represent the actual sizes or actual relative sizes of the components of the micro-LED display device.

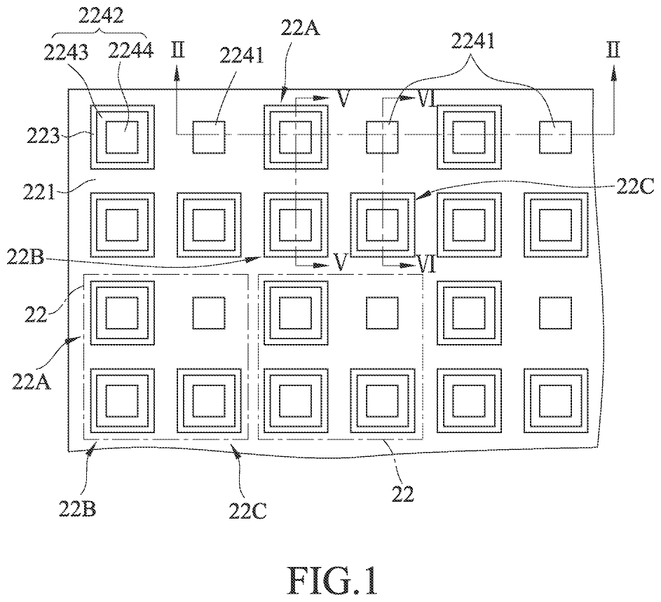

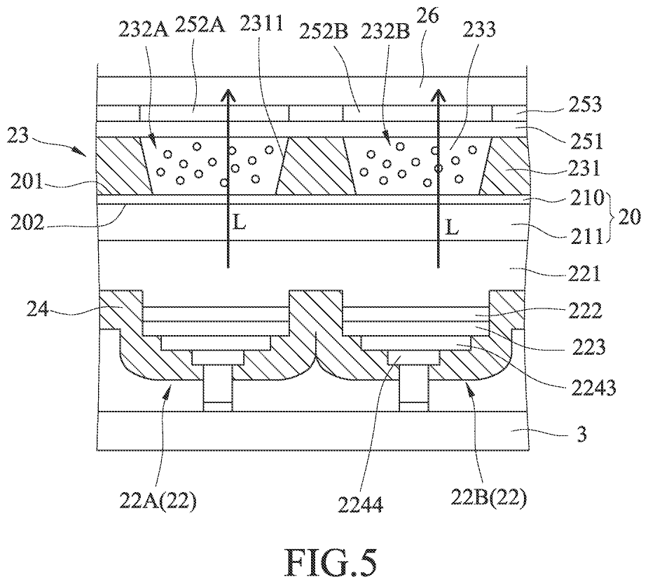

Referring to FIGS. 1 to 6, a first embodiment of a micro-LED display device 2 according to the disclosure, such as a common-cathode micro-LED display device, includes a light-transmissive unit 20, a plurality of light emitting units 22 and a plurality of converting units 23. The light-transmissive unit 20 includes a protective layer 210 which has a first surface 201 and a second surface 202 opposite to the first surface 201, and a light transmissible substrate 211 disposed to separate the protective layer 210 from the light emitting units 22.

The protective layer 210 is made of an organic material or an inorganic material, and has a thickness that is equal to or smaller than 2 μm. The light transmissible substrate 211 is made of a native substrate for epitaxial growth of the light emitting units 22. The native substrate may be made of a material selected from a light transmissible material (such as sapphire or gallium nitride), silicon (for large-area fabrication) or a semiconductor material suitable for epitaxial growth. In this embodiment, in order to avoid influencing the light extraction of the light emitting units 22, the light transmissible substrate 211 is made of, but is not limited to, sapphire.

The light emitting units 22 are arranged in an array on the second surface 202 of the protective layer 210. Each of the light emitting units 22 includes a first light emitting portion 22A, a second light emitting portion 22B, and a third light emitting portion 22C which emit lights (L) with the same original wavelength. In this embodiment, the original wavelength of lights (L) emitted from the first, second and third light emitting portions 22A, 22B, 22C ranges from 440 nm to 490 nm, i.e., the first, second and third light emitting portions 22A, 22B, 22C respectively emit blue lights.

Each of the first, second and third light emitting portions 22A, 22B, 22C includes a first type semiconductor layer 221, a light emitting layer 222 and a second type semiconductor layer 223 which are sequentially stacked on the second surface 202 of the protective layer 210. The first type semiconductor layer 221 may be one of a p-type semiconductor layer and an n-type semiconductor layer, and the second type semiconductor layer 223 is the other one of the p-type semiconductor layer and the n-type semiconductor layer. In this embodiment, the first type semiconductor layer 221 is the n-type semiconductor layer, and the second type semiconductor layer 223 is the p-type semiconductor layer.

The first type semiconductor layer 221, the light emitting layer 222 and the second type semiconductor layer 223 of each of the first, second and third light emitting portions 22A, 22B, 22C may be respectively formed of semiconductor materials to permit the first, second and third light emitting portions 22A, 22B, 22C to emit the desired original color of lights, and may be stacked together in various arrangements. In some embodiments, the first type semiconductor layer 221, the light emitting layer 222 and the second type semiconductor layer 223 of each of the first, second and third light emitting portions 22A, 22B, 22C may be made of the same semiconductor material but with different conductive types of dopants and doping concentrations. In some embodiments, the first type semiconductor layer 221, the light emitting layer 222 and the second type semiconductor layer 223 of each of the first, second and third light emitting portions 22A, 22B, 22C may be made of different semiconductor materials.

The lights (L) respectively from the first, second and third light emitting portions 22A, 22B, 22C are permitted to pass through the light-transmissive unit 20 to emit outward from the first surface 201 of the protective layer 210. The first type semiconductor layers 221 of the first, second and third light emitting portions 22A, 22B, 22C are integrally formed, while the light emitting layers 222 of the first, second and third light emitting portions 22A, 22B, 22C are spaced apart from one another. The second type semiconductor layers 223 of the first, second and third light emitting portions 22A, 22B, 22C are also spaced apart from one another.

The light emitting layer 222 has a length and a width, each of which is not greater than 100 μm. In some embodiments, each of the length and the width of the light emitting layer 222 ranges from 10 μm to 20 μm. In this embodiment, each of the light emitting units 22 includes three light emitting portions 22A, 22B, 22C. In some embodiments, the number of light emitting portions in each of the light emitting units 22 may be varied based on demands or designs.

Each of the light emitting units 22 further includes a reflecting layer 24 which is formed to cover the first, second and third light emitting portions 22A, 22B, 22C opposite to the light-transmissive unit 20 so as to direct the lights (L) from the first, second and third light emitting portions 22A, 22B, 22C toward the light-transmissive unit 20.

The converting units 23 are disposed on the first surface 201 of the protective layer 210 in positions corresponding to the light emitting units 22, respectively. Each of the converting units 23 includes a reflecting feature 231 formed on the first surface 201 of the protective layer 210. The reflecting feature 231 includes three inner peripheral surfaces 2311 which respectively define three through holes 233 in positions corresponding to the first, second and third light emitting portions 22A, 22B, 22C of the respective light emitting unit 22, respectively. The reflecting feature 231 is made of a material which reflects a broad wavelength range of light. An included angle (θ) between the first surface 201 of the protective layer 210 and each of the inner peripheral surfaces 2311 is greater than 90 degrees and less than 180 degrees, thereby forming tapered through holes 233. In some embodiments, the reflecting features 231 of the converting units 23 may be integrally formed.

Each of the converting units 23 further includes a first wavelength converting element 232A and a second wavelength converting element 232B which are respectively formed in two of the through holes 233 in positions corresponding to the first and second light emitting portions 22A, 22B of the respective light emitting unit 22. The protective layer 210 is disposed to protect the first and second wavelength converting elements 232A, 232B. In the rest of the through holes 233 in positions corresponding to the third light emitting portion 22C of the respective light emitting unit 22, no wavelength converting element is positioned therein. In some embodiments, scattering particles may be disposed in the through holes 233 in positions corresponding to the third light emitting portions 22C of the light emitting units 22 by inkjet printing or other suitable semiconductor processes.

Each of the first and second wavelength converting elements 232A, 232B includes quantum dots which are excited by the light from a respective one of the first and second light emitting portions 22A, 22B so as to vary the wavelength of the light outputted therefrom. The quantum dots may have different sizes according to demands, and may be formed of a material selected from cadmium selenide (CdSe), cadmium sulfide (CdS), zinc selenide (ZnSe), perovskite or combinations thereof. In this embodiment, when the lights (L) from the first and second light emitting portions 22A, 22B respectively pass through the first and second wavelength converting elements 232A, 232B, the lights (L) are respectively converted to have a first predetermined wavelength and a second predetermined wavelength which are different from the original wavelength. In some embodiments, the first predetermined wavelength ranges from 610 nm to 720 nm (red light), and the second predetermined wavelength ranges from 500 nm to 600 nm (green light). With such arrangement, the inner peripheral surfaces 2311 in positions corresponding to the first and second light emitting portions 22A, 22B of the respective light emitting unit 23 may respectively reflect red and green lights, while the inner peripheral surface 2311 in position corresponding to the third light emitting portion 22C of the respective light emitting unit 22 may reflect blue light emitted therefrom so that the first, second and third light emitting portions 22A, 22B, 22C function as high-directional light sources.

Each of the reflecting feature 231 and the reflecting layer 24 has a micro-feature with curved and uneven surfaces. In some embodiments, each of the reflecting feature 231 and the reflecting layer has a Bragg reflection structure, such as a distributed Bragg reflector having different refraction indices. Each of the reflecting feature 231 and the reflecting layer 24 is independently made of a material selected from a metal, a metal oxide or a combination thereof. If the reflecting layer 24 is made of a metal, an insulating layer should be formed to separate the reflecting layer 24 from the first type semiconductor layer 221, the light emitting layer 222, and the second type semiconductor layer 223. In some embodiments, the material of each of the reflecting feature 231 and the reflecting layer 24 may be nitride, composite oxide or a combination thereof, such as SiN_{X}/SiOₓ or SiO₂/TiO₂. In this embodiment, each of the reflecting feature 231 and the reflecting layer 24 is formed of, but not limited to, a composite material SiO₂/Al/SiO₂.

By forming the tapered through holes 233, the first and second wavelength converting elements 232A, 232B may be retained in the reflecting feature 231, and the blue light emitted from the third light emitting portion 22C of each of the light emitting units 22 and the red and green lights outputted from the first and second wavelength converting elements 232A, 232B of the respective converting unit 23 may be reflected by the inner peripheral surfaces 2311 of the reflecting feature 231 to travel away from the respective converting unit 23. Therefore, the red, green and blue lights reflected by the inner peripheral surfaces 2311 are high-directional lights with small light exit angle. In addition, with the provision of the reflecting layer 24, more lights emitted from the first, second and third light emitting portions 22A, 22B, 22C can be ensured to be outputted from the first surface 201 of the protective layer 210.

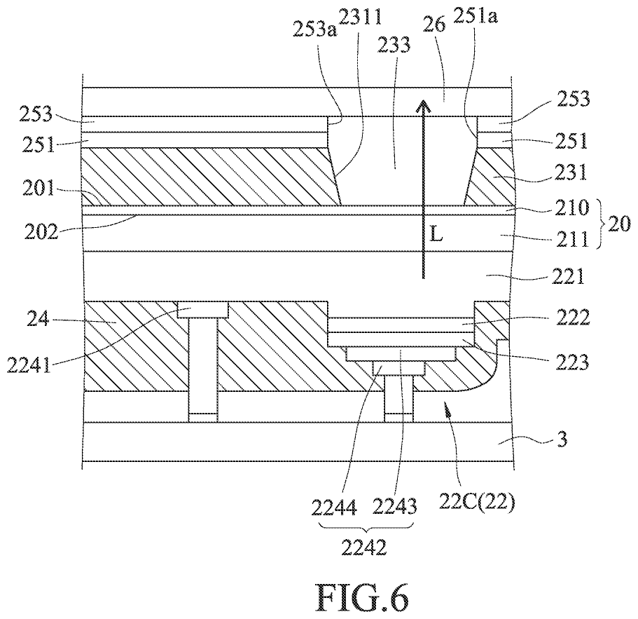

Each of the converting units 23 further includes a selective reflection layer 251 which is disposed to cover the first and second wavelength converting elements 232A, 232B opposite to the light-transmissive unit 20 so as to prevent the lights (L) with the original wavelength (which are emitted from the first and second light emitting portions 22A, 22B of the respective light emitting unit 22 and are not converted to have the first or second predetermined wavelength by the first or second wavelength converting elements 232A, 232B) from passing through the selective reflection layer 251. In this embodiment, the selective reflection layer 251 is a long-pass filter which transmit longer wavelengths of lights (i.e., red and green lights) and reflects shorter wavelengths of lights (i.e., blue lights). By forming the selective reflection layer 251 on the first and second wavelength converting elements 232A, 232B, the lights (L) with the original wavelength would be reflected and the quantum dots in the first and second wavelength converting elements 232A, 232B may convert the reflected lights into red and green lights. In this case, the number of quantum dots may be reduced and thus, the thicknesses of the first and second wavelength converting elements 232A, 232B and the reflecting feature 231 may be decreased. In some embodiments, the selective reflection layers 251 of the converting units 23 may be integrally formed to have openings 251a (see FIG. 6) in positions corresponding to the third light emitting portions 22C of the light emitting units 22 so as to permit the lights from the third light emitting portions 22C to pass through the openings 251a of the selective reflection layers 251.

Each of the converting units 23 further includes a first filter 252A, a second filter 252B and an absorbing layer 253 disposed between the respective first and second filters 252A, 252B. Each of the first and second filters 252A, 252B is disposed downstream of a respective one of the first and second wavelength converting elements 232A, 232B and the selective reflection layer 251 so as to permit the light (L) with a respective one of the first and second predetermined wavelength to pass therethrough. In this embodiment, the first filter 252A may be a red color filter for transmitting red light only, and the second filter 252B may be a green color filter for transmitting green light only. The absorbing layer 253 is formed to prevent adjacent lights from interfering each other. In some embodiments, the absorbing layers 253 of the converting units 23 may be integrally formed to have openings 253a (see FIG. 6) in positions corresponding to the third light emitting portions 22C of the light emitting units 22 so as to permit the lights from the third light emitting portions 22C to pass through the openings 253a of the absorbing layers 253. In some embodiments, a third filter (not shown) may be disposed in each of the openings 253a of the absorbing layers 253 to filter the light (L) from the third light emitting portion 22C of a respective one of the light emitting units 22.

The micro-LED display device 2 further includes a light transmissible cover plate 26 disposed to cover the converting units 23 opposite to the light-transmissive unit 20 for protecting the converting units 23, the light emitting units 22 and the light-transmissive unit 20.

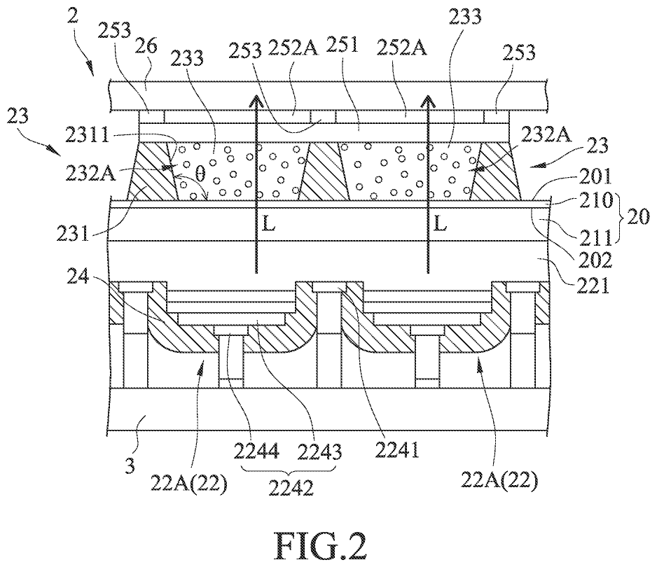

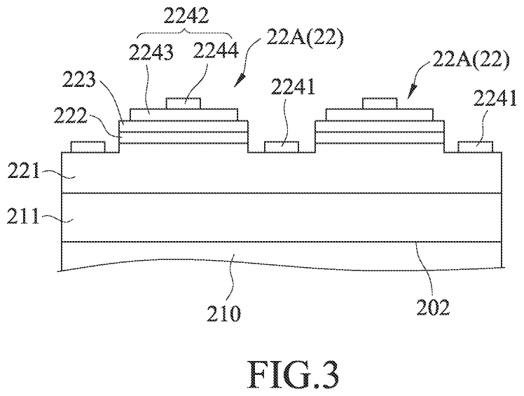

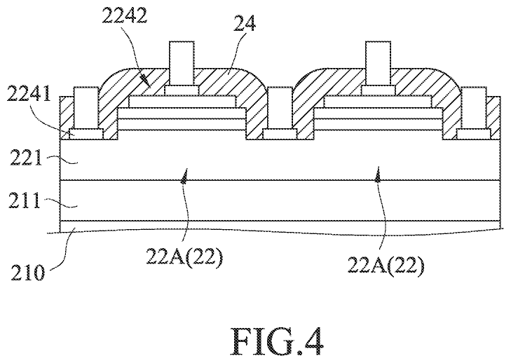

The micro-LED display device 2 further includes a circuit board 3 disposed on the light emitting units 22 opposite to the light-transmissive unit 20. Each of the light emitting units 22 further includes a first electrode 2241 and a plurality of second electrodes 2242. After the first electrode 2241 and the second electrodes 2242 are formed on each of the light emitting units 22 (see FIG. 3), the reflecting layer 24 is formed to cover the first, second and third light emitting portions 22A, 22B, 22C while exposing the first and second electrodes 2241, 2242 for electrical connection with the circuit board 3 (see FIGS. 2 and 4). The first electrode 2241 electrically connects the first type semiconductor layers 221 of the first, second and third light emitting portions 22A, 22B, 22C with the circuit board 3. Each of the second electrodes 2242 electrically connects the second type semiconductor layer 223 of a respective one of the first, second and third light emitting portions 22A, 22B, 22C with the circuit board 3, and includes a transparent conductive layer 2243 and an electrode layer 2244 disposed between the transparent conductive layer 2243 and the circuit board 3. In this embodiment, the first electrode 2241 is an n-type electrode, and each of the second electrodes 2242 is a p-type electrode. The transparent conductive layer 2243 may be made of a material selected from ITO (In₂O₃:Sn), IZO (ZnO:In) or AZO (ZnO:Al₂O₃). Each of the first electrode 2241 and the electrode layer 2244 of each of the second electrodes 2242 may be independently made of a material selected from metal or metal alloy, such as Au, In, Cu or Cu/Sn. In some embodiments, each of the first electrode 2241 and the electrode layer 2244 of each of the second electrodes 2242 may be independently formed in a single layer or multi-layers.

The light-transmissive unit 20, the light emitting units 22 and the converting units 23 cooperatively form a micro-LED display structure. The micro-LED display structure is electrically connected to the circuit board 3 by flip chip bonding instead of mass transfer.

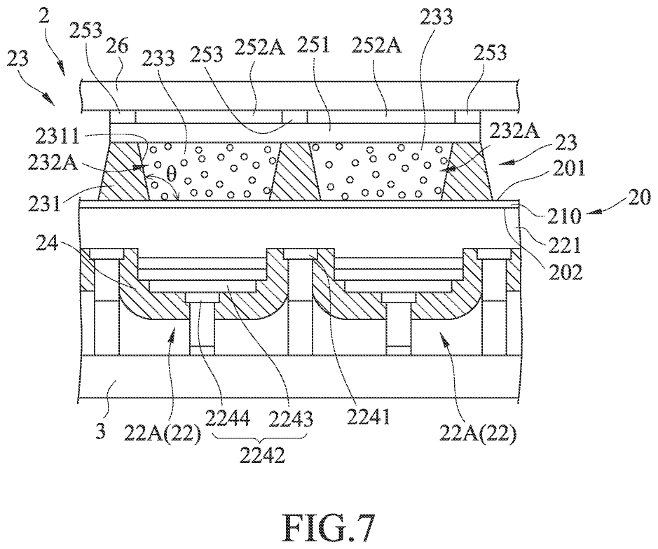

Referring to FIG. 7, a variation of the first embodiment of the micro-LED display device 2 according to the disclosure is shown. In this variation, the light-transmissive unit 20 only includes a protective layer 210. During fabrication, the light emitting units 22 are firstly formed on the light transmissible substrate 211 (see FIGS. 3 and 4) and the resulted structure is electrically connected to the circuit board 3 by flip chip bonding. Then, the light transmissible substrate 211 is removed, and the protective layer 210 is directly formed to permit the second surface 202 of the protective layer 210 to be in contact with the first type semiconductor layers 221 of the light emitting units 22, followed by forming the converting units 23 on the first surface 201 of the protective layer 210 in positions corresponding to the light emitting units 22.

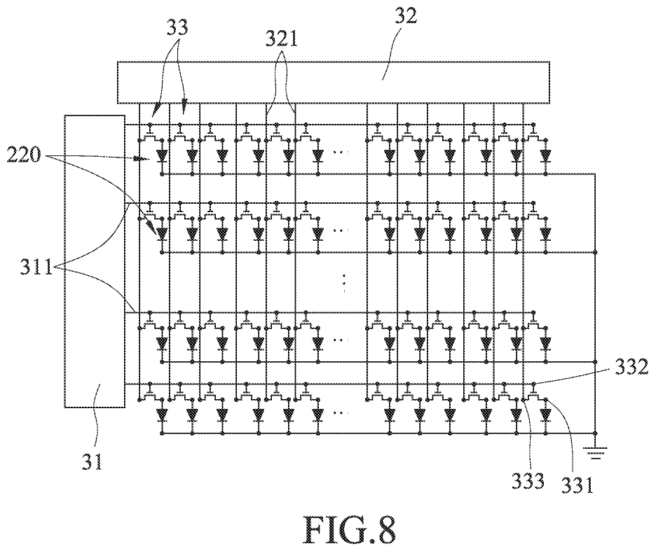

Referring to FIG. 8, a circuit diagram illustrating an operation of the first embodiment shown in FIG. 1 is shown. The first, second and third light emitting portions 22A, 22B, 22C shown in FIGS. 1 to 7 are arranged in rows and columns, and are all represented by the same numeral 220 in FIG. 8 to illustrate micro-LEDs. The circuit board 3 includes a first driving circuit 31, a second driving circuit 32, and a plurality of transistors 33. The first driving circuit 31 includes a plurality of scan lines 311 which extend in a row direction, and which are displaced from one another in a column direction transverse to the row direction. The second driving circuit 32 includes a plurality of data lines 321 which extend in the column direction, and which are displaced from one another in the row direction. The transistors 33 are arranged in rows and columns. Each of the transistors 33 includes a first electrode 331, a second electrode 332, and a third electrode 333. The first electrodes 331 of the transistors 33 are electrically connected to the first, second and third light emitting portions 220 (i.e., elements 22A, 22B, 22C shown in FIGS. 1-7), respectively. Each of the scan lines 311 is electrically connected to the second electrodes 332 of a corresponding row of the transistors 33, and each of the data lines 321 is electrically connected to the third electrodes 333 of a corresponding column of the transistors 33.

In this embodiment, the transistors 33 are p-channel transistors. To be specific, the first electrode 331 is a drain electrode, the second electrode 332 is a gate electrode, and the third electrode 333 is a source electrode. Therefore, each of the data lines 321 is electrically connected to the source electrodes 333 of the corresponding column of the transistors 33 for providing driving current to the corresponding column of the transistors 33, and each of the scan lines 311 is electrically connected to the gate electrodes 332 of the corresponding row of the transistor 33 so as to permit the corresponding row of the transistor 33 to receive timing signals, and so as to control the on and off states of the corresponding row of the transistors 33. The anode of each of the micro-LEDs 220 is electrically connected to the drain electrode 331 of each of the transistors 33, and the cathode of each of the micro-LEDs 220 is electrically connected to a ground circuit. In this manner, the transistors 33 may drive each of the micro-LEDs 220 according to the timing signal with the driving current sequentially provided to each of the micro-LEDs 220. In some embodiments, the transistors 33 may be n-channel transistors. In this case, the first electrode 331 is a source electrode, the second electrode 332 is a gate electrode, and the third electrode 333 is a drain electrode. That is, each of the data lines 321 is electrically connected to the drain electrodes 333 of the corresponding column of the transistors 33, and the anode of each of the micro-LEDs is electrically connected to the source electrode 331 of each of the transistors 33.

It should be noted that the choice of using re-channel or p-channel transistors depends on the substrate material of the circuit board 3. If the substrate of the circuit board 3 is made of glass, an n-channel amorphous silicon thin-film transistor may be fabricated or p-channel or n-channel low-temperature polycrystalline silicon (LIPS) thin-film transistor may be fabricated. If the substrate of the circuit board 3 is made of silicon, a p-channel transistor or an n-channel transistor may be fabricated.

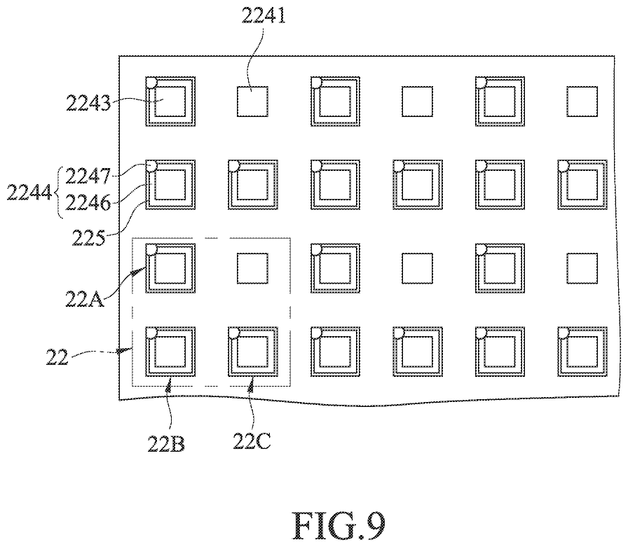

Referring to FIG. 9, a second embodiment of a micro-LED display device 2 according to the disclosure is similar to the first embodiment except for the second electrodes 2242. In this embodiment, the transparent conductive layer 2243 is disposed on a central region of the second type semiconductor layer 223 to expose a peripheral region of the second type semiconductor layer 223. The electrode layer 2244 of the second electrode 2242 of each of the first, second and third light emitting portions 22A, 22B, 22C includes a ring-shaped electrode part 2246 formed on the transparent conductive layer 2243 and a detecting electrode part 2247 disposed to be in contact with a portion of the ring-shaped electrode part 2246 and a portion of the peripheral region of the second type semiconductor layer 223 (see FIGS. 1 and 2). Uniform current spreading may be achieved with the ring-shaped electrode part 2246 and the transparent conductive layer 2243, and detecting convenience may be achieved with the detecting electrode part 2247.

Each of the first, second and third light emitting portions 22A, 22B, 22C further includes an insulating layer 225 which is disposed to separate the first type semiconductor layer 221 and the light emitting layer 222 (see FIGS. 1 and 2) from a corresponding one of the second electrodes 2242.

In overall, the micro-LED display device 2 includes a plurality of common-cathode light emitting units 22 which is electrically connected to the circuit board 3 by flip chip bonding through the first and second electrodes 2241, 2242. The micro-LED display device 2 according to the disclosure may be fabricated to avoid the problem of using mass transfer technique, i.e., each light emitting portions should be individually transferred to the native substrate first and then applied to different displays. Further, by providing the included angle (e) greater than 90 degrees, the lights (L) emitted from the micro-LED display device 2 are high-directional and have small angle light distribution which reduces the light loss therefrom. Moreover, with the formation of the reflecting layer 24 on the first, second and third light emitting portions 22A, 22B, 22C, more reflected lights may be generated to increase the amount of lights (L) exiting from the first surface 201 of the protective layer 210. Additionally, the deposition of the selective reflection layer 251 may reduce the amount of the quantum dots in the wavelength converting elements 232A, 232B, thus shortening the height of the first and second wavelength converting elements 232A, 232B and the reflecting feature 231, while achieving the same color conversion efficiency.

In the description above, for the purposes of explanation, numerous specific details have been set forth in order to provide a thorough understanding of the embodiments. It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure.

While the disclosure has been described in connection with what are considered the exemplary embodiments, it is understood that this disclosure is not limited to the disclosed embodiments but is intended to cover various arrangements included within the spirit and scope of the broadest interpretation so as to encompass all such modifications and equivalent arrangements.

What is claimed is:

1. A micro light emitting diode (micro-LED) display device, comprising:
a light-transmissive unit including a protective layer which has a first surface and a second surface opposite to said first surface;
a plurality of light emitting units arranged in an array on said second surface of said protective layer, each of said light emitting units including a first light emitting portion, a second light emitting portion, and a third light emitting portion which emit lights with the same original wavelength, each of said first, second and third light emitting portions including a first type semiconductor layer, a light emitting layer and a second type semiconductor layer which are sequentially stacked on said second surface of said protective layer such that the lights respectively from said first, second and third light emitting portions are permitted to pass through said light-transmissive unit to emit outward from said first surface of said protective layer, and such that said first type semiconductor layers of said first, second and third light emitting portions are integrally formed while said light emitting layers of said first, second and third light emitting portions are spaced apart from one another; and
a plurality of converting units disposed on said first surface of said protective layer in positions corresponding to said light emitting units, respectively, each of said converting units includes:
a reflecting feature formed on said first surface of said protective layer, and including three inner peripheral surfaces which respectively define three through holes in positions corresponding to said first, second and third light emitting portions of said respective light emitting unit, respectively, an included angle between said first surface of said protective layer and each of said inner peripheral surfaces being greater than 90 degrees, and
a first wavelength converting element and a second wavelength converting element which are respectively formed in two of said through holes in positions corresponding to said first and second light emitting portions of said respective light emitting unit such that when the lights from said first and second light emitting portions respectively pass through said first and second wavelength converting elements, the lights from said first and second light emitting portions are respectively converted to have a first predetermined wavelength and a second predetermined wavelength which are different from the original wavelength.

2. The micro-LED display device of claim 1, wherein said light-transmissive unit further includes a light transmissible substrate disposed to separate said protective layer from said light emitting units.

3. The micro-LED display device of claim 1, wherein each of said converting units further includes a selective reflection layer which is disposed to cover said first and second wavelength converting elements opposite to said light-transmissive unit so as to prevent the lights with the original wavelength from said first and second light emitting portions of said respective light emitting unit from passing through said selective reflection layer.

4. The micro-LED display device of claim 3, wherein each of said converting units further includes a first filter and a second filter, each of which is disposed downstream of a respective one of said first and second wavelength converting elements and said selective reflection layer so as to permit the light with a respective one of the first and second predetermined wavelength to pass therethrough.

5. The micro-LED display device of claim 4, further comprising a light transmissible cover plate disposed to cover said converting units opposite to said light-transmissive unit.

6. The micro-LED display device of claim 1, wherein each of said light emitting units further includes a reflecting layer which is formed to cover said first, second and third light emitting portions opposite to said light-transmissive unit so as to direct the light from said first, second and third light emitting portions toward said light-transmissive unit.

7. The micro-LED display device of claim 6, wherein each of said reflecting feature and said reflecting layer has a Bragg reflection structure.

8. The micro-LED display device of claim 7, wherein each of said reflecting feature and said reflecting layer is independently made of a material selected from the group consisting of a metal, a metal oxide and a combination thereof.

9. The micro-LED display device of claim 1, wherein the original wavelength ranges from 440 nm to 490 nm.

10. The micro-LED display device of claim 9, wherein the first predetermined wavelength ranges from 610 nm to 720 nm, and the second predetermined wavelength ranges from 500 nm to 600 nm.

11. The micro-LED display device of claim 1, wherein said light emitting layer has a length and a width, each of which is not greater than 100 μm.

12. The micro-LED display device of claim 11, wherein each of the length and the width of said light emitting layer ranges from 10 μm to 20 μm.

13. The micro-LED display device of claim 1, further comprising a circuit board disposed on said light emitting units opposite to said light-transmissive unit, each of said light emitting units further includes:
a first electrode which electrically connects said first type semiconductor layers of said first, second and third light emitting portions with said circuit board; and
a plurality of second electrodes, each of which electrically connects said second type semiconductor layer of a respective one of said first, second and third light emitting portions with said circuit board, each of said second electrodes including a transparent conductive layer and an electrode layer disposed between said transparent conductive layer and said circuit board.

14. The micro-LED display device of claim 13, wherein said transparent conductive layer is disposed on a central region of said second type semiconductor layer to expose a peripheral region of said second type semiconductor layer, and wherein said electrode layer includes a ring-shaped electrode part formed on said transparent conductive layer and a detecting electrode part disposed to be in contact with a portion of said ring-shaped electrode part and a portion of said peripheral region of said second type semiconductor layer.

15. The micro-LED display device of claim 14, wherein each of said first, second and third light emitting portions further includes an insulating layer which is disposed to separate said first type semiconductor layer and said light emitting layer from a corresponding one of said second electrodes.

16. The micro-LED display device of claim 13,
wherein said first, second and third light emitting portions are arranged in rows and columns;
wherein said circuit board includes:
a first driving circuit including a plurality of scan lines which extend in a row direction, and which are displaced from one another in a column direction transverse to the row direction;
a second driving circuit including a plurality of data lines which extend in the column direction, and which are displaced from one another in the row direction; and
a plurality of transistors which are arranged in rows and columns, each of said transistors including a first electrode, a second electrode, and a third electrode, said first electrodes of said transistors being electrically connected to said first, second and third light emitting portions, respectively;
wherein each of said scan lines is electrically connected to said second electrodes of a corresponding row of said transistors, and
wherein each of said data lines is electrically connected to said third electrodes of a corresponding column of said transistors.
